(19) United States
(12) Patent Application Publication
(10) Pub. No.: US 2025/0126703 A1
(43) Pub. Date: Apr. 17, 2025

(54) PRINTED CIRCUIT BOARD AND METHOD OF MANUFACTURING THE SAME

(71) Applicant: SAMSUNG ELECTRO-MECHANICS CO., LTD., Suwon-si (KR)

(72) Inventor: Seung Min LEE, Suwon-si (KR)

(73) Assignee: SAMSUNG ELECTRO-MECHANICS CO., LTD., Suwon-si (KR)

(21) Appl. No.: 18/734,089

(22) Filed: Jun. 5, 2024

(30) Foreign Application Priority Data
Oct. 12, 2023 (KR) 10-2023-0135919
Dec. 22, 2023 (KR) 10-2023-0189429

(51) Int. Cl. H05K 1/02; H05K 1/09; H05K 1/11; H05K 1/18; H05K 3/10; H05K 3/40

(52) U.S. Cl. CPC H05K 1/0271; H05K 1/09; H05K 1/111; H05K 1/181; H05K 3/10; H05K 3/4007; H05K 2201/068

(57) ABSTRACT

A printed circuit board includes an insulating layer, a wiring layer disposed on the insulating layer and including a plurality of metal pads and at least one metal pattern, and a solder resist layer disposed on an upper portion of the insulating layer, covering at least a portion of the wiring layer, and having a plurality of first openings respectively exposing at least a portion of each of the plurality of metal pads and one or more second openings respectively exposing at least a portion of the at least one metal pattern. The one or more second openings respectively have at least two concave portions concave in a plane toward an inside of each of the second openings. The plurality of first openings and the one or more second openings are disposed in a mounting area of a semiconductor chip of the solder resist layer.

### CROSS-REFERENCE TO RELATED APPLICATION(S)

This application claims benefit of priority to Korean Patent Application No. 10-2023-0189429 filed on Dec. 22, 2023 and Korean Patent Application No. 10-2023-0135919 filed on Oct. 12, 2023 in the Korean Intellectual Property Office, the disclosures of which are incorporated herein by reference in their entirety.

### TECHNICAL FIELD

The present disclosure relates to a printed circuit board and a method of manufacturing the same.

When mounting a semiconductor chip on a package substrate, solder balls may be used as bumps. For example, the semiconductor chip and the package substrate may be connected by contacting a connection pad formed on the semiconductor chip with a solder ball formed on the outermost side of the package substrate. On the other hand, in the process of mounting such a semiconductor chip, the degrees of bending of the semiconductor chip and the package substrate while they are heated may be different due to a difference in coefficients of thermal expansion between the semiconductor chip and the package substrate. As a result, since stress may be concentrated on the bumps at edges of the semiconductor chip, cracks may occur in the bumps.

### SUMMARY

An aspect of the present disclosure is to provide a printed circuit board and a method of manufacturing the same in which adhesion between a semiconductor chip and a package substrate when mounting the semiconductor chip may be improved.

An aspect of the present disclosure is to provide a printed circuit board and a method of manufacturing the same, in which cracks may be prevented from occurring in bumps formed with microballs or the like at an edge portion of a semiconductor chip when the semiconductor chip is mounted.

According to an aspect of the present disclosure, in a mounting area of a semiconductor chip formed on an outermost solder resist layer of a board, one or more second openings are further formed to include a second opening in the form of two holes connected to each other while respectively exposing a metal pattern, in addition to a plurality of first openings that respectively expose a plurality of metal pads, and solder bumps are formed on the plurality of first and second openings, respectively, thereby being used in mounting of semiconductor chips.

According to an aspect of the present disclosure, a printed circuit board includes an insulating layer; a wiring layer disposed on the insulating layer and including a plurality of metal pads and at least one metal pattern; and a solder resist layer disposed on an upper portion of the insulating layer, covering at least a portion of the wiring layer, and having a plurality of first openings respectively exposing at least a portion of each of the plurality of metal pads and one or more second openings respectively exposing at least a portion of the at least one metal pattern. The one or more second openings respectively have at least two concave portions concave in a plane toward an inside of each of the second openings. The plurality of first openings and the one or more second openings are disposed in a mounting area of a semiconductor chip of the solder resist layer.

According to an aspect of the present disclosure, a method of manufacturing a printed circuit board includes forming a wiring layer including a plurality of metal pads and at least one metal pattern on an upper portion of the insulating layer; forming a solder resist layer covering at least a portion of the wiring layer on the upper portion of the insulating layer; and forming a plurality of first openings in the solder resist layer, respectively exposing at least portions of the plurality of metal pads, and one or more second openings respectively exposing at least a portion of the at least one metal pattern. In the forming of the plurality of first openings and the one or more second openings, each of the one or more second openings is formed to have at least two concave portions concave toward an inside of each of the second openings on a plane, and the plurality of first openings and the one or more second openings are formed in a mounting area of a semiconductor chip of the solder resist layer.

According to an aspect of the present disclosure, a printed circuit board includes an insulating layer; a wiring layer disposed on the insulating layer and including a plurality of metal pads and a metal pattern; a solder resist layer disposed on an upper portion of the insulating layer, covering at least a portion of the wiring layer, and having a plurality of first openings respectively exposing at least a portion of each of the plurality of metal pads and two openings respectively exposing at least a portion of the metal pattern, wherein the two openings are connected to each other and have at least two concave portions concave in a plane toward an inside of the two openings; a plurality of first solder bumps respectively disposed on the plurality of first openings and respectively connected to the plurality of metal pads; and a second solder bump disposed on the two openings and connected to the metal pattern.

According to an aspect of the present disclosure, a printed circuit board includes an insulating layer; a wiring layer disposed on the insulating layer and including a plurality of metal pads and a ground pattern; a solder resist layer disposed on an upper portion of the insulating layer, covering at least a portion of the wiring layer, and having a plurality of first openings respectively exposing at least a portion of each of the plurality of metal pads and two openings respectively exposing at least a portion of the ground pattern. The two openings are connected to each other and have at least two concave portions concave in a plane toward an inside of the two openings, and the ground pattern is spaced apart from and surrounds at least one or more of the plurality of metal pads on the plane.

### BRIEF DESCRIPTION OF DRAWINGS

The above and other aspects, features, and advantages of the present disclosure will be more clearly understood from the detailed following description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a schematic cross-sectional view of an example of a printed circuit board;

FIG. 4 is a plan view illustrating a schematic top view of the printed circuit board of FIG. 3;

FIG. 5 is a plan view illustrating another schematic top view of the printed circuit board of FIG. 3;

FIG. 6 is another schematic top view of the printed circuit board of FIG. 3;

FIG. 7 is another schematic top view of the printed circuit board of FIG. 3;

FIG. 8 is a cross-sectional view schematically illustrating another example of a printed circuit board;

FIG. 9 is a cross-sectional view schematically illustrating another example of a printed circuit board;

FIG. 10 is a cross-sectional view schematically illustrating another example of a printed circuit board;

FIGS. 11A to 11G are process charts schematically illustrating an example of manufacturing a printed circuit board; and

FIGS. 12A to 12F schematically illustrate processes for another example of manufacturing a printed circuit board.

### DETAILED DESCRIPTION

Hereinafter, the present disclosure will be described with reference to the accompanying drawings. The shapes and sizes of elements in the drawings may be exaggerated or reduced for clearer description.

### Electronic Device

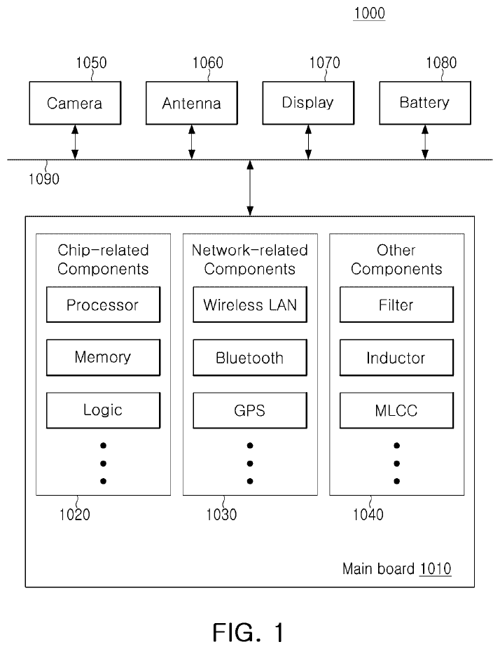

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, connected physically or electrically thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter, an application-specific integrated circuit (ASIC), or the like. However, the chip related components 1020 are not limited thereto, but may also include other types of chip related electronic components. In addition, the chip related components 1020 may also be combined with each other. The chip-related component 1020 may be in the form of a package including the aforementioned chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, and the like. In addition, other components 1040 may also be combined with the chip related components 1020 and/or the network related components 1030.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like, but are not limited thereto. These other electronic components may be an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, these other electronic components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

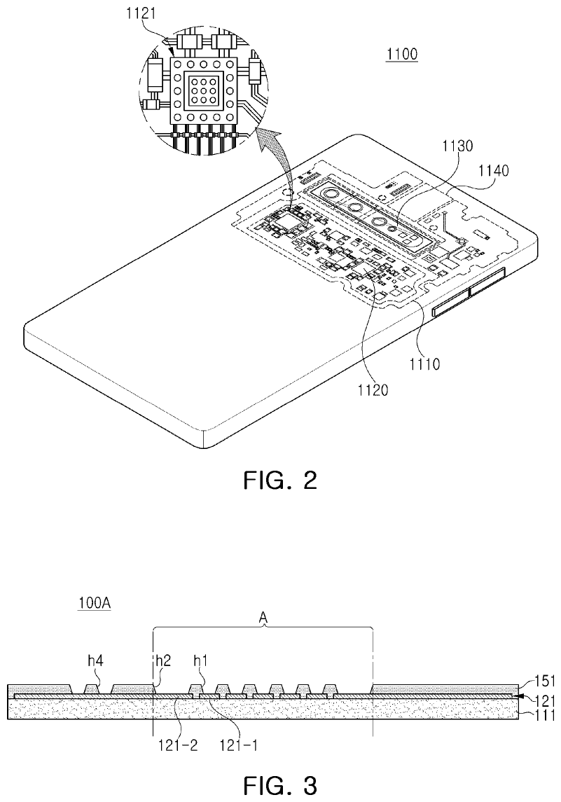

FIG. 2 is a schematic perspective view illustrating an example of an electronic device.

Referring to the drawings, the electronic device may be, for example, a smartphone 1100. A motherboard 1110 is accommodated inside the smartphone 1100, and various portions 1120 are physically and/or electrically connected to the motherboard 1110. In addition, other components that may or may not be physically and/or electrically connected to the motherboard 1110, such as a camera module 1130 and/or a speaker 1140, are accommodated therein. Some of the components 1120 may be the aforementioned chip-related components, for example, a component package 1121, but the present disclosure is not limited thereto. The component package 1121 may be in the form of a printed circuit board on which electronic components including active components and/or passive components are surface mounted. Alternatively, the component package 1121 may be in the form of a printed circuit board in which active components and/or passive components are embedded. On the other hand, the electronic device is not necessarily limited to the smartphone 1100, and may also be other electronic devices as described above.

### Printed Circuit Board

FIG. 3 is a cross-sectional view schematically illustrating an example of a printed circuit board.

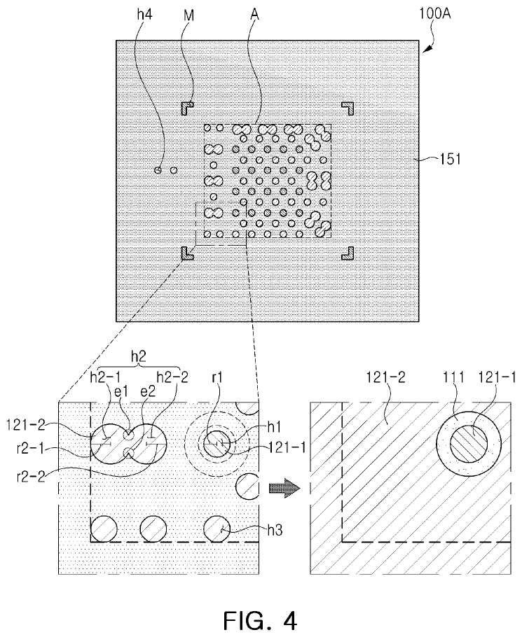

FIG. 4 is a plan view illustrating a schematic top view of the printed circuit board of FIG. 3.

Referring to the drawings, a printed circuit board 100A according to an example may include an insulating layer 111, a wiring layer 121 disposed on the upper portion of the insulating layer 111, and a solder resist layer 151 disposed on the upper portion of the insulating layer 111 and covering at least a portion of the wiring layer 121. The wiring layer 121 may include a plurality of metal pads 121-1 and at least one metal pattern 121-2. The solder resist layer 151 may have a plurality of first openings h1 exposing at least portions of the plurality of respective metal pads 121-1, and one or more second openings h2 exposing at least a portion of each of the at least one metal pattern 121-2. The plurality of first openings h2 and one or more second openings h2 may be disposed in a mounting area A of the semiconductor chip.

Each of the plurality of first openings h1 may have one opening. On the other hand, the one or more second openings h2 may respectively have two openings h2-1 and h2-2 connected to each other, and each may have more openings if necessary. Respective openings h2-1 and h2-2 may penetrate through the solder resist layer 151 in the thickness direction in the cross section, and on a plane, may have a predetermined shape such as a substantially circular, oval, polygonal, or star-shaped shape. In detail, each of the openings h2-1 and h2-2 may have a substantially circular or oval shape in a plane. Accordingly, each of the one or more second openings h2 may have at least two concave portions e1 and e2 that are concave toward the inside of each of the second openings h2 on the plane.

The one or more second openings h2 may have a shape in which two openings h2-1 and h2-2 are connected so that at least portions of respective openings h2-1 and h2-2 overlap each other on a plane. Accordingly, at least two concave portions e1 and e2 of each of the one or more second openings h2 may have sharp inflection points facing each other. For example, each of the one or more second openings h2 may have a snowman shape on a plane. On the other hand, when respective openings h2-1 and h2-2 overlap each other, based on the remaining non-overlapping shapes of respective openings h2-1 and h2-2, the virtual shape when they do not overlap on each plane may be inferred. Therefore, even if it does not have a complete predetermined shape on a plane due to overlap, or the like, it may be defined as an opening used in the present disclosure.

As described above, during the process of mounting a semiconductor chip on a package substrate, bump stress distribution may occur in each location on the lower portion of the semiconductor chip due to thermal behavior, such as a difference in bending, by differences in physical properties between the package substrate and the semiconductor chip. On the other hand, in the printed circuit board 100A according to one example, one or more second openings h2, which may have two openings h2-1 and h2-2 connected to each other, in the mounting area A of the semiconductor chip, may be disposed, and in this case, when solder balls are disposed in respective openings h2-1 and h2-2 and then reflowed, for example, a double ball-shaped solder bump may be formed. Therefore, adhesion to the connected semiconductor chip may be strengthened. In addition, this second opening h2 may be disposed on the edge side of the mounting area A of the semiconductor chip, and accordingly, the solder bump formed in the second opening h2, for example in the form of a double ball, may be connected to the edge portion of the semiconductor chip. For example, a plurality of first openings h1 may be disposed in the central portion of the mounting area A, and one or more second openings h2 may be disposed in a peripheral portion surrounding the center of the mounting area A. Therefore, cracks may be more effectively prevented from occurring in the solder bump at the edge portion of the semiconductor chip on which stress is concentrated during mounting of the semiconductor chip. In addition, it is sufficiently spaced apart from the signal solder bump disposed in the center portion of the mounting area A of the semiconductor chip, thereby eliminating potential risks such as short circuit. In addition, some of the solder bumps connected to the edge of the semiconductor chip may not be connected to signals and may be arranged on the ground, and in this case, may only be responsible for bonding between the semiconductor chip and the package substrate. Therefore, for example, even if a double ball-shaped solder bump is connected to the connection pad of a semiconductor chip, it may be considered a good product. On the other hand, if the size of the second opening h2 is simply made larger than the first opening h1, errors may occur in the solder ball mounting process, and additionally, it may be difficult to control the height deviation of the solder bump. Therefore, it may be desirable to form the second opening h2 in the above-described form.

On the other hand, in the case of each of the two openings h2-1 and h2-2 of each of the one or more second openings h2, each of the maximum radii thereof r2-1 and r2-2 on the plane may be larger than a maximum radius r1 of each of the plurality of first openings h1 on the plane. In this case, the maximum radius may be the distance from the center of the opening to the furthest edge, regardless of the shape of the opening. For example, the area of each of the two openings h2-1 and h2-2 of each of the one or more second openings h2 on the plane may be larger than the area of each of the plurality of first openings h1 on the plane. In this case, the reliability of, for example, a double ball-shaped solder bump formed in one or more second openings h2 may be further improved.

On the other hand, in the case of at least one of the one or more second openings h2, a virtual line connecting the center points of each of the two openings h2-1 and h2-2 may be substantially parallel or perpendicular to the virtual edge of the mounting area A of the semiconductor chip. In addition, in the case of at least one other of the one or more second openings h2, a virtual line connecting the center points of each of the two openings h2-1 and h2-2 may be substantially parallel or perpendicular to a virtual line connecting the center point of the mounting area A of the semiconductor chip and the center point of at least one other second opening h2. For example, one or more second openings h2 may be disposed in various shapes to distribute stress. In this case, the center point may be the spatial center of the configuration on the plane.

On the other hand, the solder resist layer 151 may further have a plurality of third openings h3 respectively exposing at least another portion of the at least one metal pattern 121-2. Each of the plurality of third openings h3 may have one opening. For example, the plurality of third openings h3 may be arranged on the ground or power, and may be disposed in various spaces within the mounting area A of the semiconductor chip. Therefore, the reliability of connection with the semiconductor chip may be further improved through the solder bumps disposed on the plurality of third openings h3.

On the other hand, the mounting area A of the semiconductor chip may include a quadrangular area created by substantially connecting the outer edges of the outermost openings with the straight line among the openings including a plurality of first openings h1, one or more second openings h2, and a plurality of third openings h3. On the other hand, when defining a quadrangular area, some protruding or partially recessed portions of the outer edges of the outermost openings on the plane may be excluded when drawing a virtual line. Additionally, the angle at which different virtual straight lines meet may be substantially a right angle. For example, the quadrangular area may have a substantially rectangular or square shape in plan. The mounting area A of the semiconductor chip including this quadrangular area may be a bump area where solder bumps for mounting the semiconductor chip are formed. Therefore, when defining the quadrangular area, the plurality of fourth openings h4 or the reference mark (M) may be excluded. For example, the reference mark (M) is for mounting semiconductor chips, and may be formed near at least one corner, in detail, all four corners, of the mounting area A of the semiconductor chip, for example, a quadrangular area. In addition, the plurality of fourth openings h4 are for mounting passive components and may be formed around the mounting area A of the semiconductor chip, for example, a quadrangular area.

On the other hand, at least one of the plurality of metal pads 121-1 may be spaced apart from at least one metal pattern 121-2 and the entire side thereof may be continuously surrounded by at least one metal pattern 121-2. For example, in FIG. 4, referring to the drawing on the right, where the solder resist layer 151 is omitted from the enlarged view, a donut-shaped groove exposing the insulating layer 111 may be formed between at least one metal pattern 121-1 and at least one metal pattern 121-2 surrounding the same. For example, each of the plurality of metal pads 121-1 may include a metal pad for a signal, and at least one metal pattern 121-2 may include a metal pattern for a ground. As illustrated in the drawing, the ground metal pattern may be formed widely, and thus at least two second openings h2 may respectively expose different parts of the ground metal pattern.

On the other hand, the plurality of first openings h1 are of the Solder Mask Defined (SMD) type and may expose a portion of each of the plurality of metal pads 121-1. Additionally, the one or more second openings h2 may also be of a Solder Mask Defined (SMD) type and may respectively expose at least a portion of the at least one metal pattern 121-2. In addition, the plurality of third openings h3 are also of the Solder Mask Defined (SMD) type and may respectively expose at least another portion of the at least one metal pattern 121-2. Therefore, solder bumps may be formed more stably. However, the present disclosure is not limited thereto, and a Non Solder Mask Defined (NSMD) type, a combination of SMD and NSMD, or other modified types may be applied.

On the other hand, the printed circuit board 100A according to one example may be applied as the outermost layer of a multilayer circuit board. Multilayer circuit boards may be used as Flip-Chip Boards (FCB), Ball Grid Arrays (BGA), interposer boards, package boards, or the like. However, the present disclosure is not limited thereto and various other types of boards may be used.

Hereinafter, the components of the printed circuit board 100A according to an example will be described in more detail with reference to the drawings.

The insulating layer 111 may include an inorganic insulating material and/or an organic insulating material. Examples of the organic insulating material may include thermosetting resins such as epoxy resins, thermoplastic resins such as polyimide, or resins along with inorganic fillers, organic fillers, and/or glass fibers (Glass Fiber, Glass Cloth, Glass Fabric). For example, the organic insulating material may be Copper Clad Laminate (CCL), Prepreg (PPG), Ajinomoto Build-up Film (ABF), Photo Imageable Dielectric (PID), or the like, but is not limited thereto. The inorganic insulating material may include a glass substrate, a silicon substrate, and/or a ceramic substrate. For example, the glass substrate may include glass, and the glass may include, for example, pure silicon dioxide (about 100% SiO₂), soda lime glass, borosilicate glass, alumino-silicate glass, and the like, but the present disclosure is not limited thereto. For example, as alternative glass materials, fluorine glass, phosphoric acid glass, chalcogen glass and the like may also be used as materials of the glass. In addition, other additives may be further included to form a glass having specific physical properties. These additives include magnesium, calcium, manganese, aluminum, lead, boron, iron, chromium, potassium, sulfur and antimony, and carbonates and/or oxides of these elements and other elements, as well as calcium carbonate (for example, lime) and sodium carbonate (for example, soda). On the other hand, glass may be distinguished from glass fiber, glass cloth, and glass fabric included in organic insulating materials. Additionally, the silicon substrate may include silicon (Si), and, if necessary, may include an oxide layer formed on silicon (Si). Additionally, the silicon substrate may include a nitride layer formed on the oxide layer. On the other hand, the oxide layer may include a silicon oxide film, and the nitride layer may include a silicon nitride film, but are not limited thereto. Additionally, the ceramic substrate may include ceramic, and ceramics may include, for example, alumina (Al₂O₃), aluminum nitride (AlN), silicon carbide (SiC), silicon nitride (Si₃N₄), or the like, but are not limited thereto. The insulating layer 111 may be composed of multiple layers, if necessary.

The wiring layer 121 may include a metal. Examples of the metal may include copper (Cu), aluminum (Al), silver (Ag), tin (Sn), gold (Au), nickel (Ni), lead (Pb), titanium (Ti), and/or alloys thereof, and in detail, may include copper (Cu), but the present disclosure is not limited thereto. The wiring layer 121 may perform various functions according to design, and for example, may include a signal pattern, a power pattern, and a ground pattern. Each of these patterns may include a line pattern, a pad pattern, a plane pattern, and the like. The wiring layer 121 may include, but is not limited to, an electroless plating layer (or chemical copper) and an electrolytic plating layer (or electrolytic copper). A sputtered layer may be formed instead of an electroless plating layer, and both may be included. Additionally, copper foil may be further included. The wiring layer 121 may be disposed to protrude on the upper surface of the insulating layer 111. If necessary, the wiring layer 121 may be embedded in the insulating layer 111 and the upper surface thereof may be exposed from the upper surface of the insulating layer 111.

The solder resist layer 151 may include solder resist. The solder resist may be a photosensitive material and may also be of a liquid type. However, the solder resist is not limited thereto, and may be a non-photosensitive material or a film type. The solder resist layer 151 may have a plurality of first openings h1, one or more second openings h2, a plurality of third openings h3, and a plurality of fourth openings h4. Each of these openings may be formed as a Solder Mask Defined (SMD) type, but is not limited thereto, and a Non Solder Mask Defined (NSMD) type, or a combination of SMD and NSMD, or other modified types may be applied. The solder resist layer 151 may have a mounting area A of semiconductor chip and may have a reference mark (M) therearound.

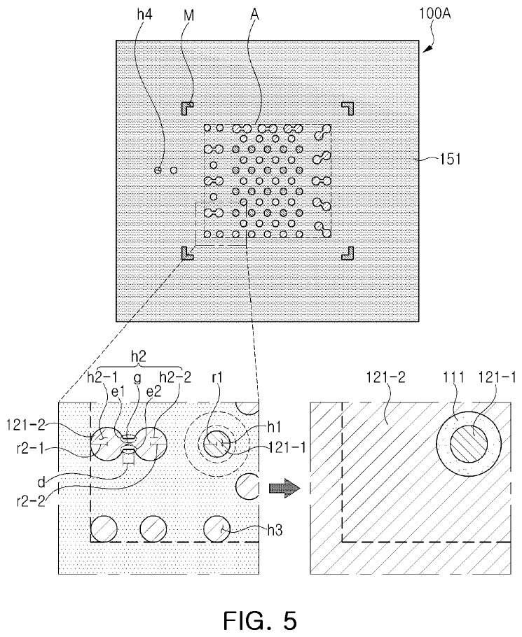

FIG. 5 is a plan view illustrating another schematic top view of the printed circuit board of FIG. 3.

Referring to the drawings, one or more second openings h2 may have a shape in which two openings h2-1 and h2-2 are spaced apart from each other on a plane and connected by a straight groove g. Accordingly, at least two concave portions e1 and e2 of each of the one or more second openings h2 may respectively have two inflection points between a curved line and a straight line. For example, each of the one or more second openings h2 may have a dumbbell shape in a plane view. The straight groove g may penetrate the solder resist layer 151 in the thickness direction on a cross-section, and may have a predetermined shape, such as a substantially quadrangle, on a plane. In this case, the above-described technical effect may also be obtained. On the other hand, when respective openings h2-1 and h2-2 are spaced apart from each other and connected by the straight groove (g), based on the remaining shapes excluding the connection portions of respective openings h2-1 and h2-2, the virtual shape when the openings h2-1 and h2-2 are not connected may be inferred. Therefore, even if it does not have a complete predetermined shape on a plane due to connection through the straight groove (g), it may be defined as an opening used in the present disclosure.

On the other hand, the length (d) of the straight groove (g) may be smaller than each of the maximum radii r2-1 and r2-2 of respective openings h2-1 and h2-2. In this case, the length d of the straight groove g may be the separation distance between respective openings h2-1 and h2-2. Additionally, as described above, the maximum radius may be the distance from the center point of the opening to the furthest edge, regardless of the shape of the opening. If the length (d) of the straight groove (g) is longer than the maximum radius r2-1, r2-2 of each of the openings h2-1 and h2-2, it may be difficult for the solder balls disposed in respective openings h2-1 and h2-2 to be connected to each other during the reflow process, and it may be difficult to control the height deviation of the solder bump.

Other than that, other contents are substantially the same as those described above, and thus redundant descriptions related thereto are omitted. On the other hand, the shape of one or more second openings h2 may be combined into various shapes, and for example, the snowman shape illustrated in FIG. 4 and the dumbbell shape illustrated in FIG. 5 may be combined and applied.

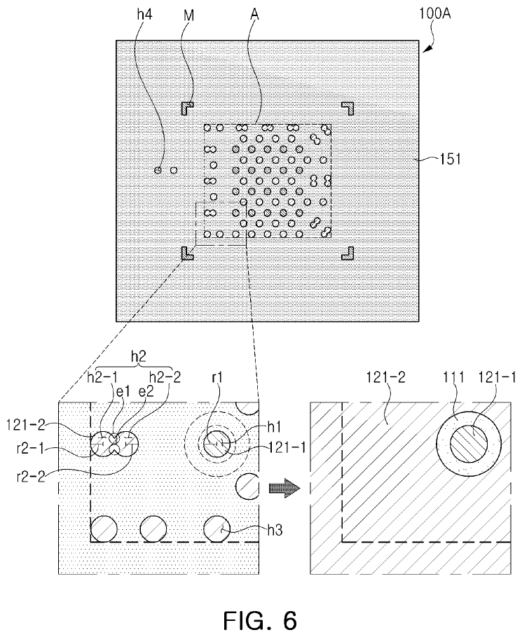

FIG. 6 is another schematic top view of the printed circuit board of FIG. 3.

Referring to the drawings, one or more second openings h2 may have a shape in which two openings h2-1 and h2-2 are connected to overlap each other on a plane. Accordingly, at least two concave portions e1 and e2 of each of the one or more second openings h2 may have sharp inflection points facing each other. For example, each of the one or more second openings h2 may have a snowman shape on a plane. At this time, in the case of each of the two openings h2-1 and h2-2 of the one or more second openings h2, each of the maximum radii r2-1 and r2-2 thereof on the plane is substantially equal to the maximum radius r1 of each of the plurality of first openings h1 on the plane, or may be smaller than the maximum radius r1 of each of the plurality of first openings h1 on the plane. In this case, the maximum radius may be the distance from the center of the opening to the furthest edge, regardless of the shape of the opening, as described above. For example, in the case of each of the two openings h2-1 and h2-2 of the one or more second openings h2, the area thereof on the plane may be substantially the same as the area of each of the plurality of first openings h1 on the plane, or may be smaller than the area of each of the plurality of first openings h1 on the plane. In this case, when mounting the solder ball in each of the plurality of first openings h1, solder balls may also be mounted in one or more second openings h2, respectively, and a reflow process may be performed at the same time. Therefore, the process may be more simplified.

Other than that, the other contents are substantially the same as above, and thus any redundant description related thereto will be omitted.

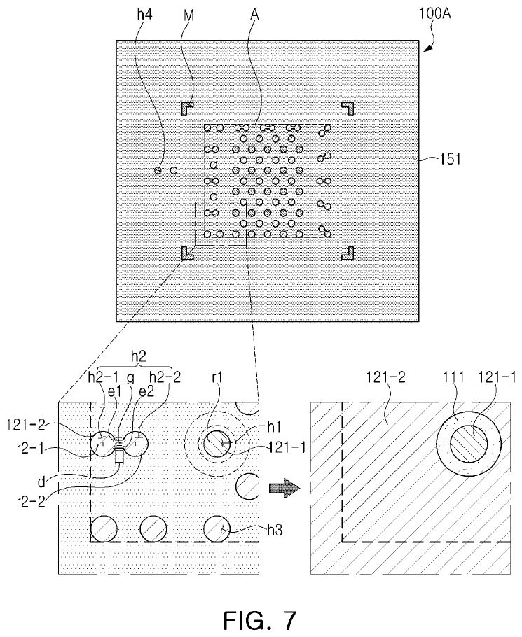

FIG. 7 is another schematic top view of the printed circuit board of FIG. 3.

Referring to the drawings, one or more second openings h2 may have a shape in which two openings h2-1 and h2-2 are spaced apart from each other on a plane and connected by a straight groove g. Accordingly, at least two concave portions e1 and e2 of each of the one or more second openings h2 may respectively have two inflection points between curved lines and a straight line. For example, each of the one or more second openings h2 may have a dumbbell shape in a plane view. At this time, in the case of the respective two openings h2-1 and h2-2 of each of the one or more second openings h2, each of the maximum radii r2-1 and r2-2 thereof on the plane is substantially equal to the maximum radius r1 of each of the plurality of first openings h1 on the plane, or may be smaller than the maximum radius r1 of each of the plurality of first openings h1 on the plane. In this case, the maximum radius may be the distance from the center of the opening to the furthest edge, regardless of the shape of the opening, as described above. For example, in the case of each of the two openings h2-1 and h2-2 of the one or more second openings h2, the area thereof on the plane may be substantially the same as the area of each of the plurality of first openings h1 on the plane, or may be smaller than the area of each of the plurality of first openings h1 on the plane. In this case, when mounting solder balls in the plurality of respective first openings h1, solder balls may be mounted in one or more second openings h2, and a reflow process may be performed at the same time. Therefore, the process may be more simplified.

The other contents are substantially the same as those described above, and thus redundant descriptions related thereto are omitted. On the other hand, the shape of one or more second openings h2 may be combined into various shapes, and for example, the snowman shape illustrated in FIG. 6 and the dumbbell shape illustrated in FIG. 7 may be applied in combination.

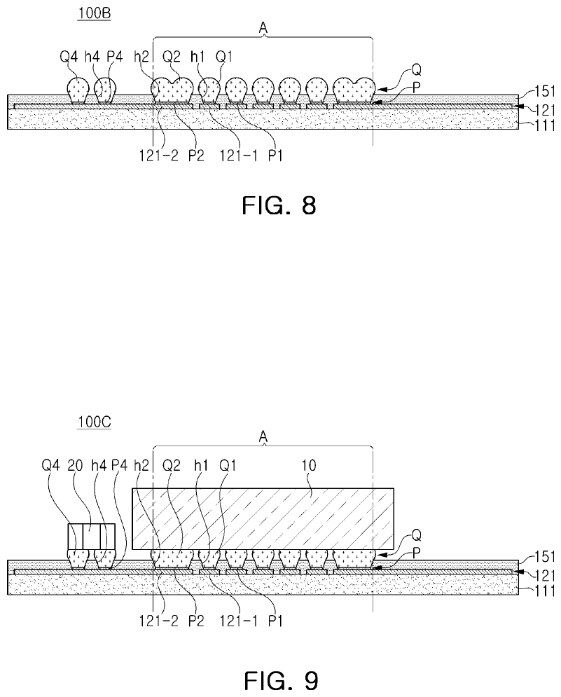

FIG. 8 is a cross-sectional view schematically illustrating another example of a printed circuit board.

Referring to the drawings, compared with the printed circuit board 100A according to the above-described example, a printed circuit board 100B according to another example may further include a surface treatment layer P that includes a first surface treatment layer P1 disposed within the plurality of first openings h1 and covering the exposed surface of each of the plurality of metal pads, and a second surface treatment layer P2 disposed within one or more second openings h2 and covering the exposed surface of at least one metal pattern, and a solder layer Q that includes a plurality of first solder bumps Q1 respectively disposed on the plurality of first openings h1 and respectively connected to the plurality of metal pads (121-1) through the first surface treatment layer P1, and one or more second solder bumps Q2 respectively disposed on one or more second openings h2 and respectively connected to at least one metal pattern (121-2) through the second surface treatment layer P2.

On the other hand, the surface treatment layer P may further include a third surface treatment layer (not illustrated) disposed on the surface of the metal pattern 121-2 exposed through a plurality of third openings (not illustrated). Additionally, the solder layer Q may further include a plurality of third solder bumps (not illustrated) respectively connected to the third surface treatment layer (not illustrated). In addition, the surface treatment layer P may further include a fourth surface treatment layer P4 disposed on the surface of the metal pattern 121-2 exposed through the plurality of fourth openings h4. In addition, the solder layer Q may further include a plurality of fourth solder bumps Q4 respectively connected to the fourth surface treatment layer P4.

On the other hand, the solder layer Q may have excellent flatness before the semiconductor chip 10 is mounted. For example, among a plurality of first solder bumps Q1, one or more second solder bumps Q2, a plurality of third solder bumps (not illustrated), and a fourth solder bump Q4, the height difference between the solder bump with the maximum height and the solder bump with the minimum height may be within approximately 20 μm. In this case, the deviation in bump height may be reduced by improving process capability, thereby improving the yield and quality of assembly, and the cause of bump height defects during substrate manufacturing may be eliminated, thereby further improving yield. In this regard, the shape and size of each opening and groove of the one or more second openings h2 described above may be controlled so that the height difference of the solder bump described above may be maintained.

Hereinafter, the components of the printed circuit board 100B according to another example will be described in more detail with reference to the drawings.

The surface treatment layer P may be formed by, for example, electrolytic gold plating, electroless gold plating, Organic Solderability Preservative (OSP), electroless tin plating, electroless silver plating, electroless nickel plating/substituted gold plating, and Electroless Nickel Electroless palladium Immersion Gold (ENEPIG), Direct Immersion Gold (DIG) plating, Hot Air Solder Leveling (HASL), or the like, but the present disclosure is not limited thereto. For example, the surface treatment layer P may be formed through one or more of electroless nickel plating, electroless palladium plating, and substitutional gold plating. Accordingly, the first to fourth surface treatment layers (P1, P2, not illustrated, and P4) may each include one or more of a nickel layer, a palladium layer, and a gold layer, and in detail, each may include all thereof, but the present disclosure is not limited thereto.

The solder layer Q may be formed of a low melting point metal, for example, tin (Sn)-aluminum (Al)-copper (Cu) solder, or the like, but this is only an example. The material thereof is not particularly limited thereto. The first, third and fourth solder bumps (Q1, not illustrated, and Q4) may respectively have a micro ball shape, and the second solder bump Q2 may respectively have a shape in which at least two micro balls are connected to each other by reflow, for example, a double ball shape. The double ball may have a convex portion on each top surface, but is not limited thereto, and may have a single convex portion at the center of the top surface, or the top face thereof may be flat throughout.

Other than that, other contents are substantially the same as those described above, so redundant descriptions related thereto are omitted. On the other hand, it goes without saying that the above-mentioned contents described through FIGS. 4 to 7 may also be applied to the printed circuit board 100B according to another example.

FIG. 9 is a cross-sectional view schematically illustrating another example of a printed circuit board.

Referring to the drawings, a printed circuit board 100C according to another example may include a semiconductor chip 10 and a passive component 20 respectively disposed on the solder resist layer 151, in the printed circuit board 100B according to another example described above. The semiconductor chip 10 may be disposed on the mounting area A of the semiconductor chip, and the passive component 20 may be disposed therearound. The semiconductor chip 10 may include a plurality of connection pads connected to the respective first to third solder bumps (Q1, Q2, not illustrated). The passive component 20 may include a plurality of external electrodes respectively connected to the fourth solder bump Q4.

Hereinafter, the components of the printed circuit board 100C according to another example will be described in more detail with reference to the drawings.

The semiconductor chip 10 may include an integrated circuit (IC) die in which hundreds to millions of devices or more are integrated into a single chip. In this case, the integrated circuit may be a logic chip such as, for example, a central processor (for example, a CPU), a graphics processor (for example, a GPU), a field programmable gate array (FPGA), a digital signal processor, a cryptographic processor, a microprocessor, a microcontroller, an application processor (for example, AP), an analog-to-digital converter, an application-specific IC (ASIC), or the like, but is not limited thereto, and may also be a memory chip such as a volatile memory (for example, DRAM), a non-volatile memory (for example, ROM), a flash memory, a high bandwidth memory (HBM), or other types such as Power Management ICs (PMICs). The number of semiconductor chips 10 may be plural, and in this case, semiconductor chips of the same type or different types may be respectively disposed on the mounting area A of the semiconductor chip.

The semiconductor chip 10 may be formed based on an active wafer, and in this case, silicon (Si), germanium (Ge), gallium arsenide (GaAs), or the like may be used as a base material constituting each body. Various circuits may be formed in the body. A plurality of connection pads may be formed on each body, and each of the plurality of connection pads may include a conductive material such as aluminum (Al) or copper (Cu). The semiconductor chip 10 may be a bare die, and in this case, each metal bump may be disposed on the connection pad as required. The semiconductor chip 10 may be a packaged die, and in this case, an additional redistribution layer is formed on the plurality of connection pads, and a plurality of metal bumps may be disposed on the redistribution layer, as required.

The passive component 20 may be a chip component, and for example, may be a high frequency inductor, a ferrite inductor, a power inductor, ferrite beads, low temperature co-firing ceramics (LTCC), Electro Magnetic Interference (EMI), a Multilayer Ceramic Capacitor (MLCC), or the like, but is not limited thereto. The passive component 20 may be plural, and respective passive components 20 may be of the same or different type.

Other than that, other contents are substantially the same as those described above, and thus, redundant descriptions related thereto are omitted. On the other hand, it goes without saying that the above-mentioned contents described through FIGS. 4 to 7 may also be applied to the printed circuit board 100C according to another example.

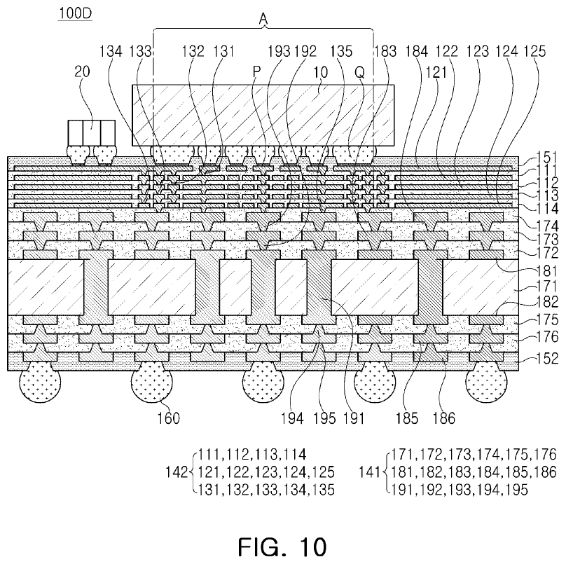

FIG. 10 is a cross-sectional view schematically illustrating another example of a printed circuit board.

Referring to the drawings, a printed circuit board 100D according to another example may be a multilayer semiconductor package structure including the printed circuit board 100C according to another example described above as an outermost configuration. For example, the printed circuit board 100D according to another example may include a core-type first substrate portion 141, a coreless-type second substrate portion 142 disposed on the first substrate portion 141, first and second solder resist layers 151 and 152 respectively disposed on the first and second substrate portions 141 and 142, a surface treatment layer P respectively disposed in the plurality of openings of the first solder resist layer 151 and respectively connected to exposed at least portions of the uppermost third build-up wiring layer 121, a solder layer Q including a plurality of solder bumps respectively disposed on a plurality of openings of the first solder resist layer 151 and respectively connected to the surface treatment layer P, a semiconductor chip 10 and a passive component 20 disposed on the first solder resist layer 151 and respectively connected to the third build-up wiring layer 121 of the uppermost layer through the solder layer Q, and a plurality of electrical connection metals 160 respectively disposed on a plurality of openings of the second solder resist layer 152 and respectively connected to exposed at least portions of the second build-up wiring layer 186 of the lowest layer.

On the other hand, the second substrate portion 142 may have a higher wiring density than the first substrate portion 141. For example, the second substrate portion 142 may include high-density wiring with a relatively finer pitch than the first substrate portion 141, and the first substrate portion 141 may include relatively lower density wiring than the second substrate portion 142. For example, the wiring of the second substrate portion 142 may be relatively smaller in thickness, line/space, pitch, or the like than the wiring of the first substrate portion 141. Additionally, the insulation distance between wires disposed on different layers may be smaller. For example, the printed circuit board 100D according to another example may include a 2.nD package board.

Hereinafter, the components of the printed circuit board 100D according to another example will be described in more detail with reference to the drawings.

The first substrate portion 141 may be a core-type multilayer substrate. For example, the first substrate portion 141 may include a core insulation layer 171, first and second core wiring layers 181 and 182 respectively disposed on the upper and lower surfaces of the core insulating layer 171, a core via layer 191 that penetrates the core insulating layer 171 and connects the first and second core wiring layers 181 and 182, a plurality of first build-up insulating layers 172, 173, and 174 disposed on the upper surface of the core insulating layer 171, a plurality of first build-up wiring layers 183 and 184 respectively disposed on or within the plurality of first build-up insulating layers 172, 173 and 174, a plurality of first build-up via layers 192 and 193 respectively penetrating at least one of the plurality of first build-up insulating layers 172, 173 and 174 and respectively connected to at least one of the plurality of first build-up wiring layers 183 and 184, a plurality of second build-up insulating layers 175 and 176 disposed on the lower surface of the core insulating layer 171, a plurality of second build-up wiring layers 185 and 186 respectively disposed on or within the plurality of second build-up insulating layers 175 and 176, and a plurality of second build-up via layers 194 and 195 respectively penetrating at least one of the plurality of second build-up insulating layers 175 and 176 and respectively connected to at least one of the plurality of second build-up wiring layers 185 and 186.

The core insulating layer 171 may include an organic insulating material. The organic insulating material may include thermosetting resins such as epoxy resins, thermoplastic resins such as polyimide, or materials in which these insulating resins are mixed with inorganic fillers such as silica or the like, or resins impregnated into the core material such as glass fiber (glass fibers, glass cloth, glass fabric) along with an inorganic filler, for example, insulating materials such as Copper Clad Laminate (CCL), or the like. However, the present disclosure is not limited thereto. The core insulating layer 171 may include an inorganic insulating material. The inorganic insulating material may include a glass substrate, a silicon substrate, and/or a ceramic substrate. For example, the glass substrate may include glass, and glass may include, for example, pure silicon dioxide (about 100% SiO₂), soda lime glass, borosilicate glass, alumino-silicate glass, or the like. However, the present disclosure is not limited thereto, and alternative glass materials such as fluorine glass, phosphate glass, chalcogen glass, or the like may also be used as materials for the glass layer. Additionally, other additives may be further included to form glass with specific physical properties. These additives include calcium carbonate (for example, lime) and sodium carbonate (for example, soda), as well as magnesium, calcium, manganese, aluminum, lead, boron, iron, chromium, potassium, sulfur and antimony, and carbonates and/or oxides of these elements and other elements. On the other hand, glass may be distinguished from glass fiber, glass cloth, and glass fabric included in organic insulating materials. Additionally, the silicon substrate may include silicon (Si), and, if necessary, may include an oxide layer formed on silicon (Si), and additionally, may include a nitride layer formed on the oxide layer. On the other hand, the oxide layer may include a silicon oxide film, and the nitride layer may include a silicon nitride film, but are not limited thereto. Additionally, the ceramic substrate may include ceramic, and ceramics may include, for example, alumina (Al₂O₃), aluminum nitride (AlN), silicon carbide (SiC), silicon nitride (Si₃N₄), and the like, but the present disclosure is not limited thereto. The insulating layer 111 may be composed of multiple layers, if necessary. The core insulating layer 171 may be thicker than each of the first and second build-up insulating layers 172, 173, 174, 175, and 176, but is not limited thereto.

Each of the plurality of first and second build-up insulating layers 172, 173, 174, 175, and 176 may include an organic insulating material. An organic insulating material may include thermosetting resins such as epoxy resins, thermoplastic resins such as polyimide, materials in which these insulating resins are mixed with inorganic fillers such as silica, or resins impregnated with core materials such as glass fibers along with inorganic fillers, for example, insulating materials such as Ajinomoto Build-up Film (ABF), prepreg, and Resin Coated Copper (RCC), but are not limited thereto. The number of layers of each of the plurality of first and second build-up insulating layers 172, 173, 174, 175, and 176 is not particularly limited.

The first and second core wiring layers 181 and 182 may each include a metal. Metals such as copper (Cu), aluminum (Al), silver (Ag), tin (Sn), gold (Au), nickel (Ni), lead (Pb), titanium (Ti), or alloys thereof may be used, and in detail, may contain copper (Cu). The first and second core wiring layers 181 and 182 may each include an electroless plating layer (or chemical copper) and an electrolytic plating layer (or electrical copper), but are not limited thereto. As an electroless plating layer, a sputtering layer may be formed instead of chemical copper, and both thereof may also be used. If necessary, copper foil may be further included. The first and second core wiring layers 181 and 182 may perform various functions depending on the design of each layer, and for example, may include a ground pattern, a power pattern, a signal pattern, and the like. These patterns may respectively include line patterns, plain patterns, and/or pad patterns.

Each of the plurality of first and second build-up wiring layers 183, 184, 185, and 186 may include a metal. Metals such as copper (Cu), aluminum (Al), silver (Ag), tin (Sn), gold (Au), nickel (Ni), lead (Pb), titanium (Ti), or alloys thereof may be used, and in detail, may contain copper (Cu). The plurality of first and second build-up wiring layers 183, 184, 185, and 186 may include an electroless plating layer (or chemical copper) and an electrolytic plating layer (or electrolytic copper), respectively, but are not limited thereto. As an electroless plating layer, a sputtering layer may be formed instead of chemical copper, and both may also be used. If necessary, copper foil may be further included. The plurality of first and second build-up wiring layers 183, 184, 185, and 186 may perform various functions depending on the design of each layer, and for example, may include a ground pattern, a power pattern, a signal pattern, and the like. These patterns may respectively include line patterns, plain patterns, and/or pad patterns.

The core via layer 191 may include a through-via. The through-via may include a metal layer formed on the wall of the through hole and a plug that fills the metal layer. The metal layer may contain a metal such as copper (Cu), aluminum (Al), silver (Ag), tin (Sn), gold (Au), nickel (Ni), lead (Pb), titanium (Ti), or alloys thereof, and in detail, may contain copper (Cu). The plug may contain ink as an insulating material. The metal layer may include, but is not limited to, an electroless plating layer (or chemical copper) and an electrolytic plating layer (or electrolytic copper). As an electroless plating layer, a sputtered layer may be formed instead of chemical copper, and both may also be used as needed. The core via layer 191 may perform various functions depending on the design, and for example, may include ground vias, power vias, signal vias, and the like. The core via layer 191 may have a substantially cylindrical shape, but is not limited thereto and may have a substantially hourglass shape.

Each of the plurality of first and second build-up via layers 192, 193, 194, and 195 may include microvias. Microvias may be filled vias that fill a via hole or conformal vias disposed along the wall of the via hole. Microvias may be disposed as a stacked type and/or a staggered type. The plurality of first and second build-up via layers 192, 193, 194, and 195 may each include a metal, and the metal may be copper (Cu), aluminum (Al), silver (Ag), tin (Sn), gold (Au), nickel (Ni), lead (Pb), titanium (Ti), or alloys thereof, and in detail, may contain copper (Cu). The plurality of first and second build-up via layers 192, 193, 194, and 195 may each include an electroless plating layer (or chemical copper) and an electrolytic plating layer (or electrolytic copper), but are not limited thereto. As an electroless plating layer, a sputtering layer may be formed instead of chemical copper, and both may also be used. The plurality of first and second build-up via layers 192, 193, 194, and 195 may perform various functions depending on the design of the corresponding layer, and for example, may include ground vias, power vias, signal vias, and the like. The vias of the first plurality of build-up via layers 192 and 193 and the vias of the plurality of second build-up via layers 194 and 195 may have a shape tapered in opposite directions.

The second substrate portion 142 may be a coreless type multilayer build-up substrate including a microcircuit. For example, the second substrate portion 142 may include a plurality of third build-up insulating layers 111, 112, 113 and 114, a plurality of third build-up wiring layers 121, 122, 123, 124 and 125 respectively disposed on or within the plurality of third build-up insulating layers 111, 112, 113 and 114, and a plurality of third build-up via layers 131, 132, 133, 134 and 135 respectively penetrating at least one of the plurality of third build-up insulating layers 111, 112, 113 and 114 and respectively connected to at least one of the plurality of third build-up wiring layers 121, 122, 123, 124 and 125.

Each of the plurality of third build-up insulating layers 111, 112, 113, and 114 may include an organic insulating material. Organic insulating materials may include thermosetting resins such as epoxy resins, thermoplastic resins such as polyimide, or materials in which these insulating resins are mixed with inorganic fillers such as silica, or resin impregnated into the core material such as glass fiber along with an inorganic filler, for example, insulating materials such as Ajinomoto Build-up Film (ABF), prepreg, and Resin Coated Copper (RCC), but are not limited thereto. The number of layers of the plurality of third build-up insulating layers 111, 112, 113, and 114 is not particularly limited. On the other hand, the third build-up insulating layer 111 disposed on the outermost layer among the plurality of third build-up insulating layers 111, 112, 113, and 114 may be the insulating layer 111 in the above-described printed circuit boards 100A, 100B and 100C.

The plurality of third build-up wiring layers 121, 122, 123, 124, and 125 may include a metal. The Metal such as copper (Cu), aluminum (Al), silver (Ag), tin (Sn), gold (Au), nickel (Ni), lead (Pb), titanium (Ti), or alloys thereof may be used, and in detail, may contain copper (Cu). The plurality of third build-up wiring layers 121, 122, 123, 124, and 125 may include an electroless plating layer (or chemical copper) and an electrolytic plating layer (or electrical copper), but are not limited thereto. As an electroless plating layer, a sputtering layer may be formed instead of chemical copper, and both may also be used. If necessary, copper foil may be further included. The plurality of third build-up wiring layers 121, 122, 123, 124, and 125 may perform various functions depending on the design of the corresponding layer, and for example, may include a ground pattern, a power pattern, a signal pattern, and the like. These patterns may include line patterns, plain patterns, and/or pad patterns, respectively. On the other hand, the third build-up wiring layer 121 disposed on the outermost layer among the plurality of third build-up wiring layers 121, 122, 123, 124, and 125 may be the wiring layer 121 in the above-described printed circuit boards 100A, 100B, and 100C.

Each of the plurality of third build-up via layers 131, 132, 133, 134, and 135 may include microvias. Microvias may be filled vias that fill a via hole or may be conformal vias disposed along the wall of the via hole. Microvias may be disposed as a stacked type and/or a staggered type. The plurality of third build-up via layers 131, 132, 133, 134, and 135 may include a metal, and the metal may include copper (Cu), aluminum (Al), silver (Ag), tin (Sn), gold (Au), nickel (Ni), lead (Pb), titanium (Ti), or alloys thereof, and in detail, may contain copper (Cu). The plurality of third build-up via layers 131, 132, 133, 134, and 135 may include an electroless plating layer (or chemical copper) and an electrolytic plating layer (or electrolytic copper), but are not limited thereto. As an electroless plating layer, a sputtering layer may be formed instead of chemical copper, and both may also be used. The plurality of third build-up via layers 131, 132, 133, 134, and 135 may perform various functions depending on the design of each layer, and for example, may include ground vias, power vias, signal vias, and the like. The vias of the plurality of third build-up via layers 131, 132, 133, 134, and 135 may have a shape tapered in the same direction. The vias of the plurality of third build-up via layers 131, 132, 133, 134, and 135 may have a shape tapered in the same direction as the vias of the plurality of first build-up via layers 192 and 193, and may have a shape tapered in the direction opposite to the vias of the plurality of second build-up via layers 194 and 195.

The first and second solder resist layers 151 and 152 may each include solder resist. The solder resist may be a photosensitive material and may also be of a liquid type. For example, the solder resist may be product name AUS703 or SR7300, but is not limited thereto. The first solder resist layer 151 may have a plurality of openings h and g, and respective openings h and g may expose at least portions of the third build-up wiring layer 121 on the uppermost layer. Each opening h, g is of the Solder Mask Defined (SMD) and/or Non-Solder Mask Defined (NSMD) type and may expose at least a portion of the third build-up wiring layer 121 on the uppermost layer, and in detail, may be the SMD type and expose at least a portion of the uppermost third build-up wiring layer 121. The second solder resist layer 152 may also have a plurality of openings, and each opening may expose at least a portion of the lowermost second build-up wiring layer 186. Each opening may be of the SMD and/or NSMD type and expose at least a portion of the lowermost second build-up wiring layer 186, and in detail, may be the SMD type and expose at least a portion of the second lowest build-up wiring layer 186. On the other hand, the first solder resist layer 151 of the first and second solder resist layers 151 and 152 may be the solder resist layer 151 in the above-described printed circuit boards 100A, 100B, and 100C.

The plurality of electrical connection metals 160 are configured to connect the printed circuit board 100D to a main board of an electronic device, another board or the like. The plurality of electrical connection metals 160 may respectively be connected to at least portions of the third build-up wiring layer 186 of the lowest layer. If necessary, the plurality of electrical connection metals 160 may respectively be disposed through a plurality of underbump metals. The plurality of electrical connection metals 160 may be formed of a conductive material, such as solder or the like, but this is only an example and the material is not particularly limited. The plurality of electrical connection metals 160 may each be a land, ball, pin, or the like. The plurality of electrical connection metals 160 may each be formed as a multilayer structure or a single layer structure. When formed as a multilayer structure, the plurality of electrical connection metals 160 may include copper pillars and solder formed on the copper pillar, and when formed as a single layer, the plurality of electrical connection metals 160 may include tin-silver solder or copper, but are not limited thereto.

Other than that, other contents are substantially the same as those described above, and thus redundant descriptions related thereto are omitted. On the other hand, it goes without saying that the above-mentioned contents described through FIGS. 4 to 7 may also be applied to the printed circuit board 100D according to another example.

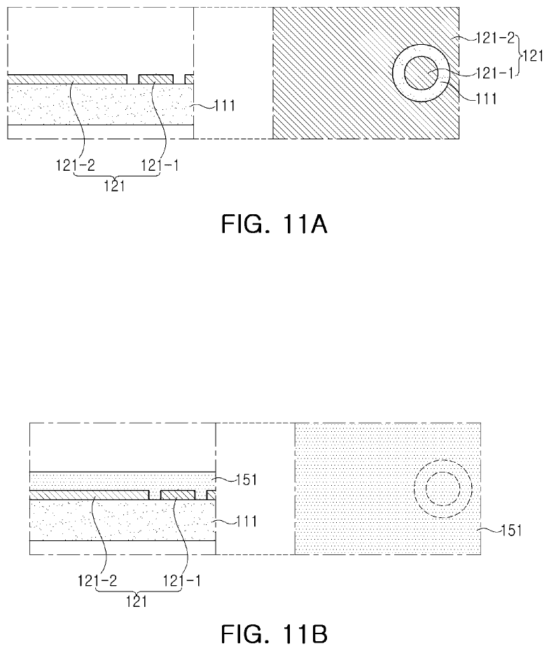

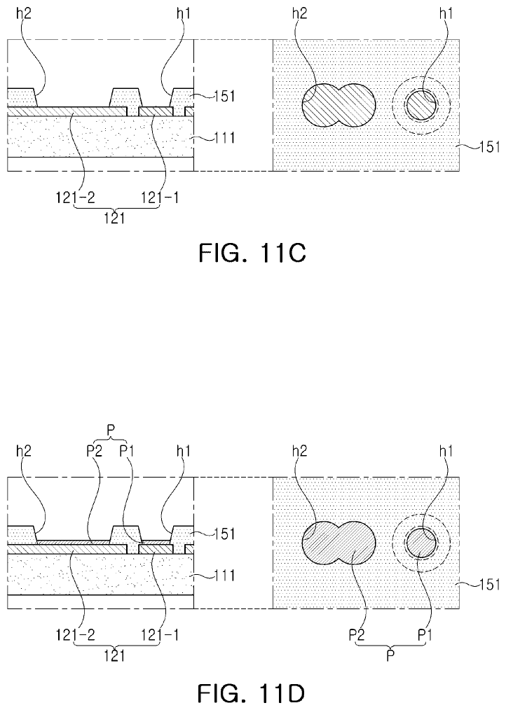

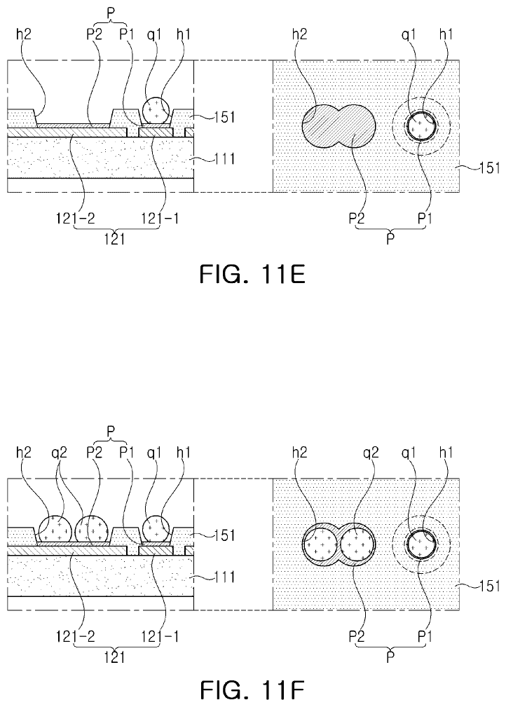

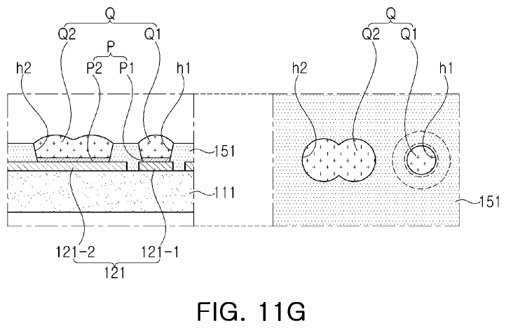

FIGS. 11A to 11G are process drawings schematically illustrating an example of manufacturing a printed circuit board. In respective drawings, the left drawing illustrates a schematic cross-sectional view at each stage, and the right drawing illustrates a schematic top-view plan view at each stage.

Referring to FIG. 11A, the wiring layer 121 may be formed on the insulating layer 111. The wiring layer 121 may include a plurality of metal pads 121-1 and at least one metal pattern 121-2. In the drawing, only a portion of the wiring layer is 121 illustrated for convenience of explanation, but as in the above-described structure, the wiring layer 121 may include more diverse patterns. The wiring layer 121 may be formed through a plating process using Additive Process (AP), Semi Additive Process (SAP), Modified SAP (MSAP), Tenting (TT), or the like.

Referring to FIG. 11B, a solder resist layer 151 may be formed on the insulating layer 111 to cover at least a portion of the wiring layer 121. The solder resist layer 151 may be formed through a coating process or a lamination process depending on the material.

Referring to FIG. 11C, in the solder resist layer 151, a plurality of first openings h1 exposing at least a portion of each of the plurality of metal pads 121-1, and one or more second openings h2 respectively exposing at least a portion of the at least one metal pattern 121-2 may be formed. In the drawings, only the first and second openings h1 and h2 are illustrated for convenience of explanation, but if necessary, the third and fourth openings (not illustrated) may also be formed. Each opening may be formed through a photolithography process or a laser processing process, depending on the material of the solder resist layer 151. One or more second openings h2 may be formed to respectively have two openings h2-1 and h2-2 connected to each other. For example, as described in FIG. 4 and the like, at least portions of the two respective openings h2-1 and h2-2 may be formed to overlap and be connected to each other on a plane. For example, the two openings h2-1 and h2-2 may be formed to have a snowman shape on a plane. Alternatively, as described in FIG. 5 and the like, the two openings h2-1 and h2-2 may be spaced apart from each other on a plane and connected to each other by a straight groove g, and for example, may be formed to have a dumbbell shape on a plane. A plurality of first openings h1 and one or more second openings h2 may be formed in the mounting area A of the semiconductor chip of the solder resist layer 151 described above. On the other hand, in the case of each of the two openings h2-1 and h2-2 of each of the one or more second openings h2, each of the maximum radii r2-1 and r2-2 on the plane may be larger than the maximum radius r1 of each of the plurality of first openings h1 on the plane. In this case, the maximum radius may be the distance from the center of the opening to the furthest edge, regardless of the shape of the opening. For example, in the case of each of the two openings h2-1 and h2-2 of each of the one or more second openings h2, the area thereof on the plane may be formed to be larger than the area of each of the plurality of first openings h1 on the plane.

Referring to FIG. 11D, a surface treatment layer P may be formed in a plurality of first openings h1 and one or more second openings h2. For example, a first surface treatment layer P1 covering the exposed surface of each of the plurality of metal pads 121-1 within the plurality of first openings h1, and a second surface treatment layer P2 covering the exposed surface of at least one metal pattern 121-2 within one or more second openings h2, may be formed. In the drawing, only the first and second surface treatment layers P1 and P2 are illustrated for convenience of explanation, but if necessary, the above-mentioned third and fourth surface treatment layers (not illustrated) may also be formed. The surface treatment layer P may be formed of Electroless Nickel Electroless Palladium Immersion Gold (ENEPIG), but the present disclosure is not limited thereto. For example, the surface treatment layer P may be formed through one or more of electroless nickel plating, electroless palladium plating, and substitutional gold plating, but is not limited thereto.

Referring to FIG. 11E, a first solder ball q1 connected to the first surface treatment layer P1 may be formed on each of the plurality of first openings h1. Next, each of the first solder balls q1 may be inspected and repaired. For example, it may be determined whether there is a defect among the first solder balls q1, the first solder ball q1 corresponding to the defect may be removed, and a first solder ball q1 may be again formed in the area where the first solder ball q1 corresponding to the defect was removed. If necessary, third and fourth solder balls (not illustrated) connected to the third and fourth surface treatment layers (not illustrated) may be formed on the third and fourth openings (not illustrated), respectively, and respectively may also be inspected and repaired. The formation of solder balls may use solder ball mounting technology. Flux may be applied as needed before mounting the solder balls.

Referring to FIG. 11F, at least two second solder balls q2 connected to the second surface treatment layer P2 may be formed on one or more second openings h2. For example, when, on a plane, the area of each of the openings h2-1 and h2-2 of each of the one or more second openings h2 is larger than the area of each of the plurality of first openings h1, a plurality of first solder balls q1 may first be formed on the plurality of first openings h1, and when inspecting and repairing the plurality of first solder balls q1 formed earlier, or later, one or more second solder balls q2 may be formed on the one or more second openings h2. If necessary, one or more second solder balls q2 may then be inspected and repaired. The size of each second solder ball q2 may be larger than the size of each first solder ball q1. The formation of solder balls may use solder ball mounting technology. Flux may be applied as needed before mounting the solder balls.

Referring to FIG. 11G, each of the first solder balls q1 and each of the second solder balls q2 may be reflowed. As a result, a solder layer Q including a plurality of first solder bumps Q1 and one or more second solder bumps Q2 may be formed. One or more second solder bumps Q2 may be in the form of at least two second solder balls q2 connected to each other. If necessary, each of the third and fourth solder balls may be reflowed, and as a result, a plurality of third and fourth solder bumps (not illustrated) may be formed. After reflowing, deflux may be performed as needed.

The above-described printed circuit boards 100A and 100B may be formed through a series of processes, and by further applying a semiconductor chip and/or passive component mounting process or a multilayer substrate forming process, the above-described printed circuit boards 100C and 100D may be formed. Other than that, other contents are substantially the same as those described above, and thus redundant descriptions related thereto are omitted. On the other hand, it goes without saying that the above-mentioned contents described through FIGS. 4 and 5 may also be applied to a method of manufacturing a printed circuit board according to an example.

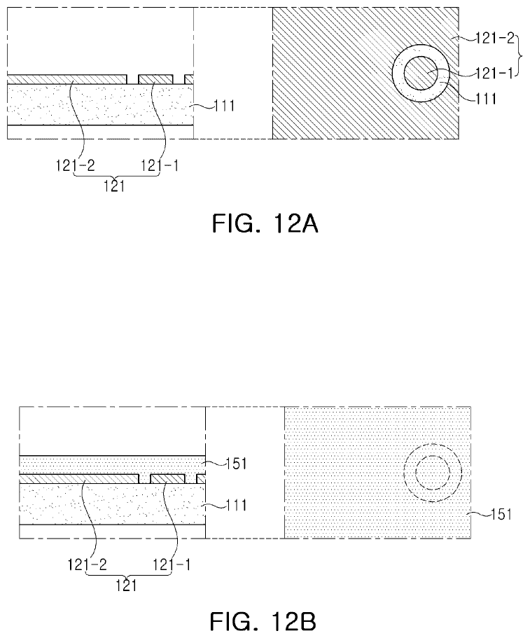

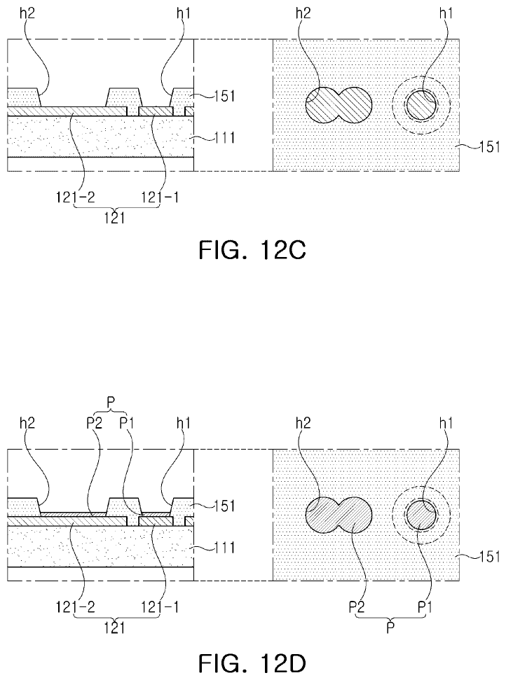

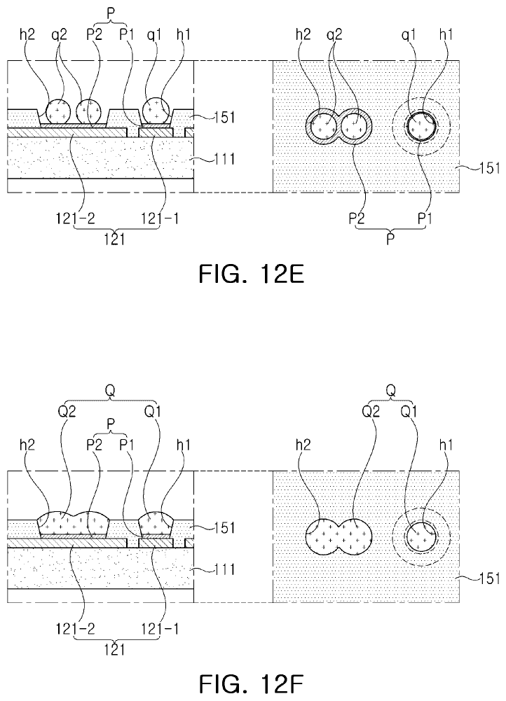

FIGS. 12A to 12F are process drawings schematically illustrating another example of manufacturing a printed circuit board. In each drawing, the left drawing illustrates a schematic cross-sectional view at each stage, and the right drawing illustrates a schematic top-view plan view at each stage.

Referring to FIG. 12A, the wiring layer 121 may be formed on the insulating layer 111. The wiring layer 121 may include a plurality of metal pads 121-1 and at least one metal pattern 121-2. In the drawing, only a portion of the wiring layer 121 is illustrated for convenience of explanation, but as in the above-described structure, the wiring layer 121 may include more diverse patterns. The wiring layer 121 may be formed through a plating process using Additive Process (AP), Semi Additive Process (SAP), Modified SAP (MSAP), Tenting (TT), or the like.

Referring to FIG. 12B, a solder resist layer 151 may be formed on the insulating layer 111 to cover at least a portion of the wiring layer 121. The solder resist layer 151 may be formed through a coating process or a lamination process depending on the material.

Referring to FIG. 12C, in the case of the solder resist layer 151, a plurality of first openings h1 exposing at least portions of the plurality of respective metal pads 121-1 and one or more second openings h2 respectively exposing at least a portion of the at least one metal pattern 121-2 may be formed. In the drawings, only the first and second openings h1 and h2 are illustrated for convenience of explanation, but if necessary, the third and fourth openings (not illustrated) may also be formed. Each opening may be formed through a photolithography process, a laser processing process or the like, depending on the material of the solder resist layer 151. One or more second openings h2 may be formed to respectively have two openings h2-1 and h2-2 connected to each other. For example, as described in FIG. 6 and the like, at least portions of the respective two openings h2-1 and h2-2 may be formed to overlap and be connected to each other on a plane, and for example, may be formed to have a snowman shape on a plane. Alternatively, as described in FIG. 7 and the like, the two openings h2-1 and h2-2 may be spaced apart from each other on a plane and connected by a straight groove g, and for example, may be formed to have a dumbbell shape on a plane. A plurality of first openings h1 and one or more second openings h2 may be formed in the mounting area A of the semiconductor chip of the solder resist layer 151 described above. On the other hand, in the case of each of the two openings h2-1 and h2-2 of each of the one or more second openings h2, each of the maximum radii r2-1 and r2-2 thereof on the plane may be larger than the maximum radius r1 of each of the plurality of first openings h1 on the plane. In this case, the maximum radius may be the distance from the center of the opening to the furthest edge, regardless of the shape of the opening. For example, in the case of each of the two openings h2-1 and h2-2 of each of the one or more second openings h2, the area thereof on the plane may be formed to be larger than the area of each of the plurality of first openings h1 on the plane.

Referring to FIG. 12D, a surface treatment layer P may be formed in a plurality of first openings h1 and one or more second openings h2. For example, a first surface treatment layer P1 covering the exposed surface of each of the plurality of metal pads 121-1 within the plurality of first openings h1 and a second surface treatment layer P2 covering the exposed surface of at least one metal pattern 121-2 within one or more second openings h2 may be formed. In the drawing, only the first and second surface treatment layers P1 and P2 are illustrated for convenience of explanation, but if necessary, the above-mentioned third and fourth surface treatment layers (not illustrated) may also be formed. The surface treatment layer P may be formed of Electroless Nickel Electroless Palladium Immersion Gold (ENEPIG), but is not limited thereto. For example, the surface treatment layer P may be formed through one or more of electroless nickel plating, electroless palladium plating, and substitutional gold plating, but is not limited thereto.

Referring to FIG. 12E, a first solder ball q1 connected to the first surface treatment layer P1 may be formed on each of the plurality of first openings h1. Additionally, at least two second solder balls q2 respectively connected to the second surface treatment layer P2 may be formed on one or more second openings h2. Next, the first solder ball q1 may be inspected and repaired. If necessary, each of the second solder balls q2 may also be inspected and repaired. For example, when on a plane, the area of the opening h2-1, h2-2 of each of the one or more second openings h2 is substantially equal to the area of each of the plurality of first openings h1 or is smaller than the area of each of the plurality of first openings h1, the solder ball formation process may be performed simultaneously, and if necessary, inspection and repair processes may also be performed simultaneously. If necessary, third and fourth solder balls (not illustrated) connected to the third and fourth surface treatment layers (not illustrated) may be formed on the third and fourth openings (not illustrated), respectively, and may also be inspected and repaired individually. The size of each second solder ball q2 may be substantially the same as or slightly smaller than the size of each first solder ball q1. The formation of solder balls may use solder ball mounting technology. Flux may be applied as needed before mounting the solder balls.

Referring to FIG. 12F, each of the first solder balls q1 and each of the second solder balls q2 may be reflowed. As a result, a solder layer Q including a plurality of first solder bumps Q1 and one or more second solder bumps Q2 may be formed. One or more second solder bumps Q2 may be in the form of at least two second solder balls q2 connected to each other. If necessary, each of the third and fourth solder balls may be reflowed, and as a result, a plurality of third and fourth solder bumps (not illustrated) may also be formed. After reflowing, deflux may be performed as needed.

The above-described printed circuit boards 100A and 100B may be formed through a series of processes, and if a semiconductor chip and/or passive component mounting process or a multilayer board forming process is further applied in this case, the above-described printed circuit boards 100C and 100D may be formed. Other than that, other contents are substantially the same as those described above, and thus redundant descriptions related thereto are omitted. On the other hand, it goes without saying that the above-mentioned contents described through FIGS. 6 and 7 may also be applied to a method of manufacturing a printed circuit board according to another example.

As set forth above, according to an embodiment, a printed circuit board and a method of manufacturing the same in which adhesion between a semiconductor chip and a package substrate when mounting the semiconductor chip may be strengthened may be provided.

A printed circuit a method of manufacturing the same, in which cracks may be prevented from occurring in bumps formed with microballs or the like at an edge portion of a semiconductor chip when the semiconductor chip is mounted may be provided.

In the present disclosure, the expression “covering” may include a case of covering at least a portion as well as a case of covering the whole, and may also include a case of directly covering as well as a case of indirectly covering. In addition, the expression to fill may include not only completely filling but also at least partially filling, and may also include approximately filling. For example, this may include cases where some voids or voids exist. In addition, the surrounding expression may include not only the case of completely surrounding, but also the case of partially surrounding and approximately surrounding. In addition, exposing may include not only completely exposing but also partially exposing, and exposure may mean exposing the corresponding component from another component that embeds the same therein. For example, another configuration may be disposed on the exposed configuration in addition to other configurations, and in this case, the meaning of exposure may be the same. In addition, in practice, the judgment may include process errors, positional deviations, and measurement errors that occur during the manufacturing process. For example, ‘substantially the same’ may include something that is approximately the same.

In the present disclosure, the meaning of cross-section may mean a cross-sectional shape when the object is vertically cut, or a cross-sectional shape when the object is viewed from a side-view. In addition, the meaning of a plane may mean a plane shape when the object is horizontally cut, or a plane shape when the object is viewed from a top-view or bottom-view.

In the present disclosure, lower, lower portion, lower surface, and the like are used to mean a downward direction based on the cross section of the drawing for convenience, and upper, upper portion, upper surface, and the like are used to mean the opposite direction. However, this is to define the direction for convenience of description, and the scope of the claims is not particularly limited by the description of this direction, of course, and the concept of upper and lower may change at any time.

In the present disclosure, the meaning of being connected is a concept including not only being directly connected but also being indirectly connected by an adhesive layer or the like. In addition, the meaning of being electrically connected is a concept including both physically connected and nonconnected cases. In addition, expressions such as first, second and the like are used to distinguish one component from another, and do not limit the order and/or importance of the components. In some cases, without departing from the scope of rights, the first element may be named a second element, and similarly, the second element may be referred to as the first element.

In the present disclosure, the meaning of penetrating may include not only penetrating completely between the upper and lower surfaces of an object based on the thickness direction or stacking direction, but also penetrating a portion from the upper surface or a portion from the lower surface in a blind form.

In the present disclosure, thickness, width, length, depth, line width, spacing, pitch, separation distance, surface roughness, and the like may be measured using a scanning microscope or an optical microscope based on a cross section obtained by polishing or cutting a printed circuit board. The cut section may be a vertical section or a horizontal section, and each value may be measured based on the required cut section. For example, the width of the upper end and/or the lower end of the via may be measured on a cross-section cut along the central axis of the via. At this time, if the value is not constant, the value may be determined as the average value of the values measured at five random points.

The expression “an (one) example” used in the present disclosure does not mean the same embodiments, and is provided to emphasize and describe different unique characteristics. However, the examples presented above are not excluded from being implemented in combination with features of other examples. For example, even if a matter described in a specific example is not described in another example, it may be understood as a description related to another example, unless there is a description contrary to or contradictory to the matter in the other example.

Terms used in this disclosure are only used to describe an example, and are not intended to limit the disclosure. In this case, singular expressions include plural expressions unless the context clearly indicates otherwise.

While example embodiments have been illustrated and described above, it will be apparent to those skilled in the art that modifications and variations could be made without departing from the scope of the present disclosure as defined by the appended claims.

What is claimed is:

1. A printed circuit board comprising:
an insulating layer;
a wiring layer disposed on the insulating layer and including a plurality of metal pads and at least one metal pattern; and
a solder resist layer disposed on an upper portion of the insulating layer, covering at least a portion of the wiring layer, and having a plurality of first openings respectively exposing at least a portion of each of the plurality of metal pads and one or more second openings respectively exposing at least a portion of the at least one metal pattern,
wherein the one or more second openings respectively have at least two concave portions concave in a plane toward an inside of each of the second openings, and
the plurality of first openings and the one or more second openings are disposed in a mounting area of a semiconductor chip of the solder resist layer.

2. The printed circuit board of claim 1, wherein the second openings respectively have a shape in which at least two openings partially overlap each other and are connected, in the plane.

3. The printed circuit board of claim 2, wherein each of the second openings has a substantially snowman shape in the plane.

4. The printed circuit board of claim 1, wherein the second openings respectively have a shape in which at least two openings are spaced apart from each other on the plane and are connected by a groove of a straight shape.

5. The printed circuit board of claim 4, wherein a length of the groove is smaller than a maximum radius of each of the openings.

6. The printed circuit board of claim 4, wherein each of the second openings has a substantially dumbbell shape in the plane.

7. The printed circuit board of claim 1, wherein the plurality of first openings respectively have one opening.

8. The printed circuit board of claim 1, wherein the solder resist layer further has a plurality of third openings respectively exposing at least another portion of the at least one metal pattern,
wherein the plurality of third openings respectively have one opening.

9. The printed circuit board of claim 8, wherein the mounting area of the semiconductor chip includes a quadrangular area created by substantially connecting, with a straight line, outer edges of outermost openings among openings including the plurality of first openings, the one or more second openings, and the plurality of third openings.

10. The printed circuit board of claim 1, wherein the plurality of first openings are disposed at a central portion of the mounting area of the semiconductor chip, and
the one or more second openings are disposed in a peripheral portion surrounding the central portion of the mounting area of the semiconductor chip.

11. The printed circuit board of claim 1, wherein at least one of the plurality of metal pads is spaced apart from the at least one metal pattern and is continuously surrounded on an entire side by the at least one metal pattern.

12. The printed circuit board of claim 1, wherein the one or more second openings are a plurality of second openings,
the at least one metal pattern includes a metal pattern for a ground, and
at least two of the plurality of second openings respectively exposing different portions of the metal pattern for the ground.

13. The printed circuit board of claim 1, wherein the plurality of first openings are of a Solder Mask Defined (SMD) type and expose portions of the plurality of metal pads, respectively, and
the one or more second openings are of a Solder Mask Defined (SMD) type and respectively expose at least a portion of the at least one metal pattern.

14. The printed circuit board of claim 1, further comprising:
a first surface treatment layer disposed within the plurality of first openings and covering at least portions of respective exposed surfaces of the plurality of metal pads; and
a second surface treatment layer disposed within the one or more second openings and covering at least a portion of an exposed surface of the at least one metal pattern.

15. The printed circuit board of claim 14, wherein the wiring layer includes a copper layer,
the first surface treatment layer includes at least one of a nickel layer, a palladium layer, and a gold layer, and
the second surface treatment layer includes at least one of the nickel layer, the palladium layer, and the gold layer.

16. The printed circuit board of claim 14, further comprising:
a plurality of first solder bumps respectively disposed on the plurality of first openings and respectively connected to the plurality of metal pads through the first surface treatment layer; and
one or more second solder bumps respectively disposed on the one or more second openings and respectively connected to the at least one metal pattern through the second surface treatment layer.

17. The printed circuit board of claim 16, further comprising a semiconductor chip disposed on the mounting area of the semiconductor chip and connected to the plurality of first solder bumps and the one or more second solder bumps.

18. The printed circuit board of claim 1, wherein the printed circuit board includes a plurality of insulating layers, a plurality of wiring layers respectively disposed on or in the plurality of insulating layers, and a plurality of via layers respectively penetrating at least one of the plurality of insulating layers and respectively connected to at least one of the plurality of wiring layers,
the insulating layer is an insulating layer disposed on an outermost layer among the plurality of insulating layers, and
the wiring layer is a wiring layer disposed on an outermost layer among the plurality of wiring layers.

19. The printed circuit board of claim 1, wherein the second openings respectively have a shape in which a first opening having a first center point and a second opening having a second center point are connected to each other on the plane, and
in at least one of the one or more second openings, a virtual line connecting the first and second center points is substantially parallel or substantially perpendicular to a virtual edge of the mounting area of the semiconductor chip.

20. The printed circuit board of claim 1, wherein the second openings have a shape in which a first opening having a first center point and a second opening having a second center point are connected to each other on a plane, and
in at least one second opening of the one or more second openings, a virtual line connecting the first and second center points substantially or is parallel substantially perpendicular to a virtual line connecting a center point of the mounting area of the semiconductor chip and a center point of the at least one second opening.

21. A method of manufacturing a printed circuit board, comprising:
forming a wiring layer including a plurality of metal pads and at least one metal pattern on an upper portion of the insulating layer;
forming a solder resist layer covering at least a portion of the wiring layer on the upper portion of the insulating layer; and
forming a plurality of first openings in the solder resist layer, respectively exposing at least portions of the plurality of metal pads, and one or more second openings respectively exposing at least a portion of the at least one metal pattern,
wherein in the forming of the plurality of first openings and the one or more second openings:
each of the one or more second openings is formed to have at least two concave portions concave toward an inside of each of the second openings on a plane, and
the plurality of first openings and the one or more second openings are formed in a mounting area of a semiconductor chip of the solder resist layer.

22. The method of claim 21, wherein in the forming of the plurality of first openings and the one or more second openings, the second openings are formed to respectively have at least two openings at least partially overlapping and connected to each other on the plane.

23. The method of claim 21, wherein in the forming the plurality of first openings and the one or more second openings, the second openings are formed such that at least two openings are spaced apart from each other on the plane and connected by a groove of a straight line.

24. The method of claim 21, further comprising forming a surface treatment layer in the plurality of first openings and the one or more second openings,
wherein in the forming the surface treatment layer,
a first surface treatment layer is formed within the plurality of first openings to cover at least a portion of an exposed surface of each of the plurality of metal pads, and
a second surface treatment layer is formed in the one or more second openings to cover at least a portion of an exposed surface of the at least one metal pattern.

25. The method of claim 24, wherein in the forming the surface treatment layer,
the first surface treatment layer is formed through one or more of electroless nickel plating, electroless palladium plating, and substitutional gold plating, and
the second surface treatment layer is formed through one or more of the electroless nickel plating, the electroless palladium plating, and the substitution gold plating.

26. The method of claim 24, further comprising forming a solder layer connected to the surface treatment layer, on the plurality of first openings and the one or more second openings,
wherein in the forming the solder layer:
a plurality of first solder bumps are formed respectively on the plurality of openings, first respectively connected to the plurality of metal pads through the first surface treatment layer, and
one or more second solder bumps respectively connected to the at least one metal pattern through the second surface treatment layer are formed on the one or more second openings, respectively.

27. The method of claim 26, wherein in the forming the solder layer,
the plurality of first solder bumps are formed by forming at least one first solder ball on each of the plurality of first openings and then reflowing, and
the one or more second solder bumps are formed by forming at least two second solder balls on each of the one or more second openings and then reflowing.

28. The method of claim 27, wherein the forming the solder layer includes forming the at least one first solder ball on each of the plurality of first openings, respectively inspecting and repairing the first solder ball, forming the at least two second solder balls on each of the one or more second openings, and respectively reflowing the first solder ball and the second solder balls, and
in the forming the plurality of first openings and the one or more second openings:
the second openings are formed to respectively have at least two openings connected to each other on the plane, and
each of the openings has a larger area on the plane than an area of each of the plurality of first openings.

29. The method of claim 27, wherein the forming the solder layer includes forming the at least one first solder ball and the at least two second solder balls on the plurality of first openings and the one or more second openings, respectively, respectively inspecting and repairing the first solder ball, and reflowing each of the first solder ball and the second solder balls, and
in the forming the plurality of first openings and the one or more second openings:
the second openings are formed to respectively have at least two openings connected to each other on the plane, and
each of the openings is formed with an area on the plane, substantially the same as an area of each of the plurality of first openings or with an area on the plane, smaller than the area of each of the plurality of first openings.

30. A printed circuit board comprising:
an insulating layer;
a wiring layer disposed on the insulating layer and including a plurality of metal pads and a metal pattern;
a solder resist layer disposed on an upper portion of the insulating layer, covering at least a portion of the wiring layer, and having a plurality of first openings respectively exposing at least a portion of each of the plurality of metal pads and two openings respectively exposing at least a portion of the metal pattern, wherein the two openings are connected to each other and have at least two concave portions concave in a plane toward an inside of the two openings;
a plurality of first solder bumps respectively disposed on the plurality of first openings and respectively connected to the plurality of metal pads; and
a second solder bump disposed on the two openings and connected to the metal pattern.

31. The printed circuit board of claim 30, wherein the two openings partially overlap each other in the plane.

32. The printed circuit board of claim 31, wherein the two openings have a substantially snowman shape in the plane.

33. The printed circuit board of claim 30, wherein the two openings are connected by a groove having a width smaller than a diameter of the two openings.

34. The printed circuit board of claim 33, wherein the two openings have a substantially dumbbell shape in the plane.

35. The printed circuit board of claim 30, wherein at least one of the plurality of metal pads is spaced apart from the metal pattern and is surrounded by the metal pattern on the plane.

36. The printed circuit board of claim 30, further comprising:
a first surface treatment layer disposed within the plurality of first openings and covering at least portions of respective exposed surfaces of the plurality of metal pads; and
a second surface treatment layer disposed within the two openings and covering at least a portion of an exposed surface of the metal pattern,
wherein the plurality of first solder bumps are respectively connected to the plurality of metal pads through the first surface treatment layer, and
the second solder bump is connected to the metal pattern through the second surface treatment layer.

37. A printed circuit board comprising:
an insulating layer;
a wiring layer disposed on the insulating layer and including a plurality of metal pads and a ground pattern;
a solder resist layer disposed on an upper portion of the insulating layer, covering at least a portion of the wiring layer, and having a plurality of first openings respectively exposing at least a portion of each of the plurality of metal pads and two openings respectively exposing at least a portion of the ground pattern,
wherein the two openings are connected to each other and have at least two concave portions concave in a plane toward an inside of the two openings, and
the ground pattern is spaced apart from and surrounds at least one or more of the plurality of metal pads on the plane.

38. The printed circuit board of claim 37, wherein the two openings partially overlap each other in the plane.

39. The printed circuit board of claim 38, wherein the two openings have a substantially snowman shape in the plane.

40. The printed circuit board of claim 37, wherein the two openings are connected by a groove having a width smaller than a diameter of the two openings.

41. The printed circuit board of claim 40, wherein the two openings have a substantially dumbbell shape in the plane.
